(19) United States
(12) Patent Application Publication
(10) Pub. No.: US 2020/0381494 A1
(43) Pub. Date: Dec. 3, 2020

(54) DISPLAY PANEL AND DISPLAY DEVICE

(71) Applicant: Wuhan China Star Optoelectronics Semiconductor Display Technology Co., Ltd, Wuhan, Hubei (CN)

(72) Inventors: Yan XIE, Wuhan, Hubei (CN); Liang Sun, Wuhan, Hubei (CN)

(21) Appl. No.: 16/631,452

(22) PCT Filed: Sep. 10, 2019
(86) PCT No.: PCT/CN2019/105179

§ 371 Date: Jan. 16, 2020

(30) Foreign Application Priority Data
May 30, 2019 (CN) 201910464504.1

(51) Int. Cl. H01L 27/32

(52) U.S. Cl. CPC H01L 27/3234; H01L 27/3262

(57) ABSTRACT

An organic light-emitting diode (OLED) display panel and a display device are provided in the present invention. The OLED display panel includes a plurality of OLED units, and each of the OLED units includes a light-emitting region and a thin film transistor (TFT) region electrically connected to the light-emitting region. The OLED display panel further includes at least one camera region configured to receive a camera, and at least one TFT collection region disposed in the at least one camera region. The TFT regions of the OLED units disposed in the at least one camera region are disposed in the at least one TFT collection region.

### FIELD OF INVENTION

The present invention relates to the field of display technologies, and in particular, to a display panel with a camera and a display device thereof.

### BACKGROUND OF INVENTION

With continuous development of display industry, small and medium size display technologies are continuously being developed, and functions on display screens are also increasing. Screens of current mobile phone displays have been widely equipped with a camera module. Since a camera device needs to be placed away from the display screen, an area available for placing the display screen is reduced, which is contrary to the development trend of increasing screen-to-body ratio of current smartphones. The camera device is an indispensable component of today's mobile phones, and how to integrate a camera with the display screen to maximize screen ratio is an urgent problem that needs to be solved.

In the conventional art, a front camera is usually designed on an outside of display screens, and whole phones need to be resized to accommodate the front camera, leading to inability of part of whole phones to display contents normally. Therefore, it is urgent to propose related technical design schemes of under-screen camera to solve the problem that full screen cannot be compatible with the front camera.

### Technical Problem

The front camera is designed on an outside of display screens, and whole phones need to be evaded to accommodate the front camera, leading to inability of part of whole phones to display contents normally. Therefore, it is urgent to propose related technical design schemes of under-screen camera to solve the problem that full screen cannot be compatible with the front camera.

### SUMMARY OF INVENTION

### Technical Solution

In order to solve aforementioned problems in the conventional art, an object of the present invention is to provide an organic light-emitting diode (OLED) display panel, the OLED display panel including a plurality of OLED units, each of the OLED units including a light-emitting region and a thin film transistor (TFT) region electrically connected to the light-emitting region. The OLED display panel further includes at least one camera region configured to receive a camera, and at least one TFT collection region disposed in the at least one camera region. The TFT regions of the OLED units disposed in the at least one camera region are disposed in the at least one TFT collection region.

In an embodiment of the present invention, the light-emitting region of each of the OLED units in the at least one camera region is connected to the corresponding TFT region in the at least one TFT collection region through a transparent metal trace.

In an embodiment of the present invention, the light-emitting regions of a portion of the OLED units in the at least one camera region overlap with the at least one TFT collection region.

In an embodiment of the present invention, the light-emitting regions and the TFT regions of the plurality of OLED units in the at least one camera region are arranged and combined with an overlapping portion and at least one non-overlapping portion.

In an embodiment of the present invention, the overlapping portion is disposed in the at least one TFT collection region.

In an embodiment of the present invention, the at least one TFT collection region in the at least one camera region is strip-shaped, and a portion of the light-emitting regions corresponding to the TFT regions in at least one the TFT collection region are disposed on a side or both sides of the at least one strip-shaped TFT collection region.

In an embodiment of the present invention, the at least one TFT collection region in the at least one camera region is in a grid shape.

In an embodiment of the present invention, each of the OLED units corresponds to a sub-pixel.

In an embodiment of the present invention, the OLED display panel further including a non-camera region, wherein the non-camera region includes at least one trace electrically connected to the light-emitting regions and the TFT regions of the OLED units in the non-camera region, wherein a size of the transparent metal trace in the at least one camera region is less than a size of the at least one trace in the non-camera region.

In order to achieve the above object, the present invention further provides an OLED display panel, the OLED display panel including a plurality of OLED units, each of the OLED units including a light-emitting region and a thin film transistor (TFT) region electrically connected to the light-emitting region. The OLED display panel further includes at least one camera region configured to receive a camera, and at least one TFT collection region disposed in the at least one camera region. The TFT regions of the OLED units disposed in the at least one camera region are disposed in the at least one TFT collection region. The light-emitting region of each of the OLED units in the at least one camera region is connected to the corresponding TFT region in the at least one TFT collection region through a transparent metal trace, and the light-emitting regions of a portion of the OLED units in the at least one camera region overlap with the at least one TFT collection region.

In an embodiment of the present invention, the light-emitting regions and the TFT regions of the plurality of OLED units in the at least one camera region are arranged and combined with an overlapping portion and at least one non-overlapping portion.

In an embodiment of the present invention, the overlapping portion is disposed in the at least one TFT collection region.

In an embodiment of the present invention, the at least one TFT collection region in the at least one camera region is strip-shaped, and a portion of the light-emitting regions corresponding to the TFT regions in the at least one TFT collection region are disposed on a side or both sides of the at least one strip-shaped TFT collection region.

In an embodiment of the present invention, the at least one TFT collection region in the at least one camera region is in a grid shape.

In an embodiment of the present invention, each of the OLED units corresponds to a sub-pixel.

In an embodiment of the present invention, the OLED display panel further including a non-camera region, wherein the non-camera region includes at least one trace electrically connected to the light-emitting regions and the TFT regions of the OLED units in the non-camera region, wherein a size of the transparent metal trace in the at least one camera region is less than a size of the at least one trace in the non-camera region.

In order to achieve the above object, the present invention further provides a display device including an organic light-emitting diode (OLED) display panel including a plurality of OLED units, each of the OLED units including a light-emitting region and a thin film transistor (TFT) region electrically connected to the light-emitting region, wherein the OLED display panel further includes at least one camera region and at least one TFT collection region disposed in the at least one camera region, wherein the TFT regions of each of the OLED units disposed in the at least one camera region are disposed in the at least one TFT collection region; and a camera disposed in the at least one camera region.

In an embodiment of the present invention, the light-emitting region of each of the OLED units in the at least one camera region is connected to the corresponding TFT region in the at least one TFT collection region through a transparent metal trace.

In an embodiment of the present invention, the light-emitting regions and the TFT regions of the plurality of OLED units in the at least one camera region are arranged and combined with an overlapping portion and at least one non-overlapping portion.

In an embodiment of the present invention, the display device further including a non-camera region, wherein the non-camera region includes at least one trace electrically connected to the light-emitting regions and the TFT regions of the OLED units in the non-camera region, wherein a size of the transparent metal trace in the at least one camera region is less than a size of the at least one trace in the non-camera region.

### Beneficial Effect

Compared with the conventional art, the OLED display panel of the present invention further includes at least one camera region configured to receive a camera, and at least one TFT collection region disposed in the camera region, wherein TFT regions of the OLED units disposed in the camera region are collectively disposed in the TFT collection region. Furthermore, the transparent metal trace is used to connect the light-emitting region and the TFT region of an individual OLED unit. Since a part of the non-transmissive metal trace is omitted, there is additional light transmittance area. Therefore, light transmittance area and light transmittance of the camera region can be increased to achieve compatibility with the camera.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain other drawings without any creative effort.

FIG. 1 is a schematic view of a display panel according to an embodiment of the present invention.

FIG. 2 is a schematic structural view of a camera region of the display panel shown in FIG. 1.

FIG. 3 is a schematic cross-sectional view taken along line Y-Y′ in FIG. 2.

FIG. 4 is a schematic structural view of a camera region of a display panel according to an embodiment of the present invention.

FIG. 5 is a schematic structural view of a camera region of a display panel according to another embodiment of the present invention.

FIG. 6 is a schematic structural view of a camera region of a display panel according to still another embodiment of the present invention.

### DETAILED DESCRIPTION OF EMBODIMENTS

The following description of each embodiment, with reference to the accompanying drawings, is used to exemplify specific embodiments which can be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

In addition, in order to avoid obscuring the invention in unnecessary detail, only the structures and/or process steps that are closely related to the aspects of the present invention are shown in the drawings.

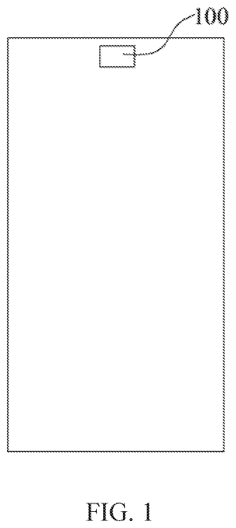

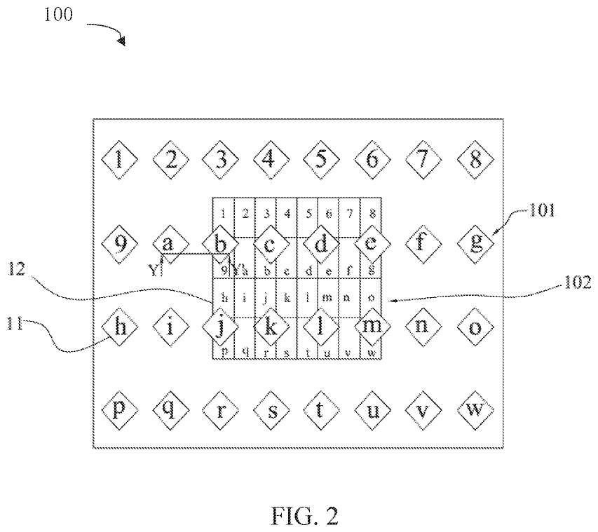

Referring to FIG. 1, a schematic diagram of an organic light-emitting diode (OLED) display panel according to an embodiment of the present invention is shown. The OLED display panel includes at least one camera region 100 and a non-camera region. Referring to FIG. 1 and FIG. 2 at the same time, where FIG. 2 is a schematic structural view of the at least one camera region 100 of the display panel shown in FIG. 1. The OLED display panel of the present embodiment includes a plurality of OLED units, each OLED unit having a light-emitting region 11 and a thin film transistor (TFT) region 12 electrically connected to the light-emitting region 11. The OLED display panel further includes at least one camera region 100 configured to receive a camera, and at least one TFT collection region 102 is disposed in the at least one camera region 100, and all TFT regions of all OLED units in the at least one camera region 100 are collectively disposed in the TFT collection region 102. The correspondence relationship between the light-emitting region and the TFT region of each OLED unit, and the TFT collection region 102 in the at least one camera region 100 will be described in detail below. For convenience of description, the present embodiment is described with one camera region 100. It should be clearly understood by those skilled in the art that the camera region 100 of the present invention can be a camera region 100 corresponding to one camera, or a plurality of camera regions 100 corresponding to one camera, which is not limited to this invention.

Referring to FIG. 2, in the embodiment, the camera region 100 has a total of 32 OLED units distributed in 4 rows by 8 columns, and each OLED unit has a light-emitting region and a TFT region. All light-emitting regions 101 of the 32 OLED units are distributed in diamond patterns of numbers 1-9, a-w in FIG. 2, and all TFT regions corresponding to the 32 OLED units are distributed in rectangular patterns of numbers 1-9, a-w in FIG. 2. Among them, the 32 TFT regions are adjacently arranged and concentrated in the TFT collection region 102. The light-emitting region and the TFT region constitute a sub-pixel, and the TFT region includes at least one driving TFT and at least one switching TFT. The number of TFT in a TFT region varies depending on product requirements, and the present invention is not limited thereto.

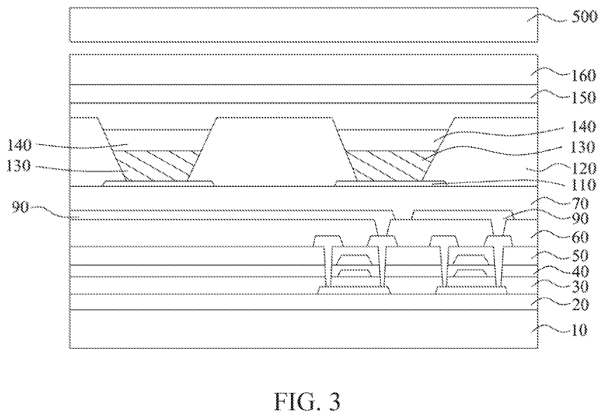

Referring to FIG. 2 and FIG. 3 at the same time, where FIG. 3 is a schematic cross-sectional view of the camera region 100 corresponding to position of section line Y-Y′ in FIG. 2. FIG. 3 shows the TFT region of the OLED unit in the TFT collection region 102, corresponding to a rectangular pattern of number 9. The TFT region 9 is exemplified by two thin film transistors, wherein structure from bottom to top comprises a glass substrate or a flexible substrate 10, a buffer layer 20, a first gate insulating layer 30, a semiconductor layer between the first gate insulating layer 30 and the buffer layer 20, a first gate disposed on the first gate insulating layer 30, a second gate insulating layer 40 covering the first gate, a second gate disposed on the second gate insulating layer 40, an intermediate dielectric layer 50 covering the second gate, an organic filling layer or a first planarization layer 60 disposed on the intermediate dielectric layer 50, the organic filling layer or the first planarization layer 60 covering a source, a drain, and the intermediate dielectric layer 50, a transparent conductive layer 90 disposed on the organic filling layer or the first planarization layer 60, and a second planarization layer 70 disposed on the first planarization layer 60 and the transparent conductive layer 90. Then, an OLED device is disposed on the TFT region 9. The OLED device includes at least an anode 110, a pixel definition layer 120, an organic light-emitting layer 130, a cathode 140, a moisture barrier layer 150, and a cover plate 160, which are disposed in a stack. The organic light-emitting layer 130 between two adjacent pixel definition layers 120 is a light-emitting region. FIG. 3 shows that two organic light-emitting layers 130 are corresponding to a part of the light-emitting region a and a part of the light-emitting region b in FIG. 2. Two TFTs of the TFT region 9 are shown in FIG. 3, wherein a left TFT is connected to the light-emitting region 9 shown in FIG. 2 through the transparent conductive layer 90. The two organic light-emitting layers 130 shown in FIG. 3, that is, the light-emitting region a and the light-emitting region b in FIG. 2, are connected to the TFT region a and the TFT region b in the TFT collection region 102, which are rectangular pattern a and rectangular pattern b shown in FIG. 2 through different traces. The trace between the light-emitting region and the TFT region of the same OLED unit is made of a transparent metal trace, which can be the transparent conductive layer 90 disposed above the first planarization layer 60 or disposed above another layer such as an intermediate dielectric layer 50 as shown in FIG. 3, the invention is not limited thereto.

In an embodiment, in the camera region 100, the trace between the light-emitting region and the TFT region of the same OLED unit, in addition to employing the transparent metal trace, a size of the trace in the camera region can be less than a size of the trace in the non-camera region. Therefore, light transmittance of the camera region 100 can be further increased.

In this embodiment, the OLED units of the camera region 100 and the non-camera region, wherein the light-emitting region and the TFT region of each OLED unit are the same in function and design, the difference lies in relative position of space and connection manner of the trace. In the OLED units in the non-camera region, dense non-transmissive metal trace between the light-emitting region and the TFT region of the individual OLED unit blocks light from entering and affects imaging of the camera. Therefore, the present invention integrates the TFT regions of each OLED unit of the camera region 100 in one TFT collection region 102, and the transparent metal trace is used to connect the light-emitting region and the TFT region of the individual OLED unit. Since a part of the non-transmissive metal trace is omitted, there is additional light transmittance area. The light transmissive area and light transmittance of the camera region 100 can be increased to achieve compatibility with the camera.

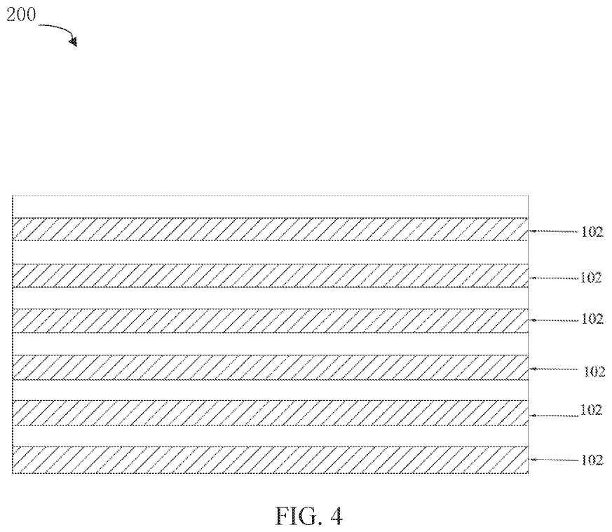

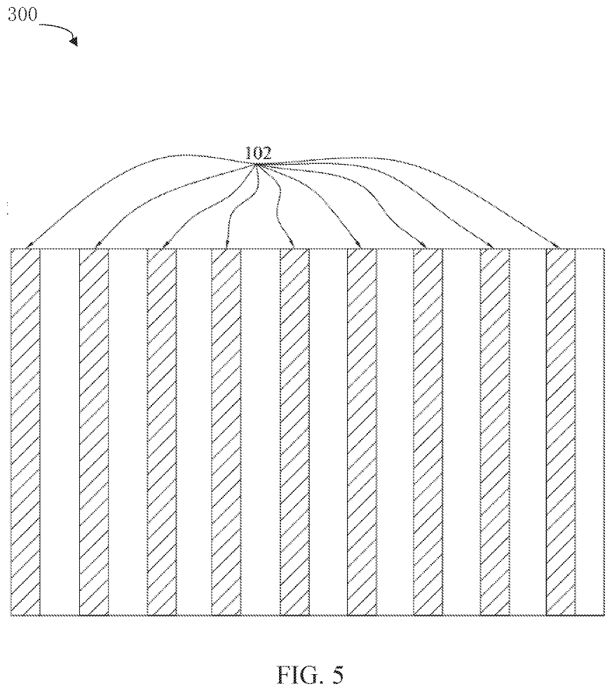

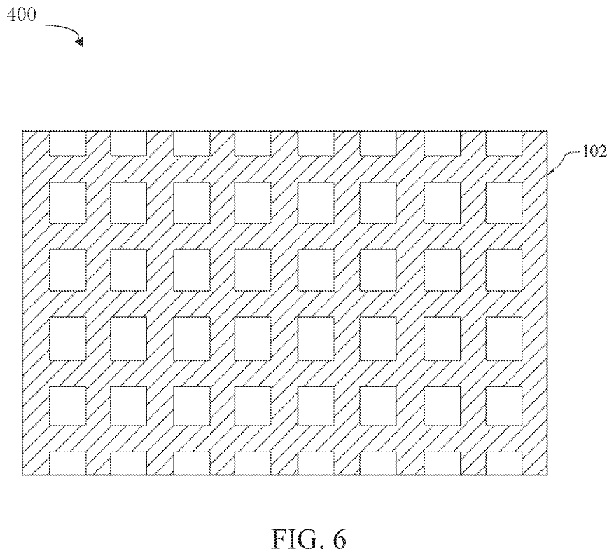

Please refer to FIG. 4, FIG. 5, and FIG. 6, which are schematic structural diagrams of three other embodiments of a camera region of a display panel according to the present invention. Some parts and components are the same as those of the foregoing embodiment, which are not repeated here and only the difference is explained. FIG. 4, FIG. 5, and FIG. 6 show relative arrangement positions of light-emitting regions and TFT regions of all OLED units in the camera region 100 after different arrangement and combination. The light-emitting regions and the TFT regions of the plurality of OLED units in the at least one camera region are arranged and combined with an overlapping portion and at least one non-overlapping portion, the corresponding TFT collection regions 102 can also be set to different patterns. The TFT collection region 102 can be arranged in a strip-shape as shown in FIG. 4 and FIG. 5, where FIG. 4 shows that the strip-shaped arrangement is alternately staggered line by line, and FIG. 5 shows that the strip-shaped arrangement is vertically staggered column by column. FIG. 6 shows that the TFT collection region 102 is disposed in a grid shape. Opaque metal traces are absent from the non-overlapping portions of the light-emitting regions and the TFT regions, thereby increasing light transmittance of the camera region 100 of the display panel.

In an embodiment, the display panel further includes a touch panel 500 disposed on the OLED units.

Furthermore, the present invention further provides a display device, including the display panel in the foregoing embodiments, and a camera disposed in the camera region 100.

Embodiments of the present invention have been described above, but are not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) display panel, comprising:
a plurality of OLED units, each of the OLED units comprising a light-emitting region and a thin film transistor (TFT) region electrically connected to the light-emitting region, wherein the OLED display panel further comprises:
at least one camera region configured to receive a camera, and
at least one TFT collection region disposed in the at least one camera region, wherein the TFT regions of the OLED units disposed in the at least one camera region are disposed in the at least one TFT collection region.

2. The OLED display panel according to claim 1, wherein the light-emitting region of each of the OLED units in the at least one camera region is connected to the corresponding TFT region in the at least one TFT collection region through a transparent metal trace.

3. The OLED display panel according to claim 1, wherein the light-emitting regions of a portion of the OLED units in the at least one camera region overlap with the at least one TFT collection region.

4. The OLED display panel according to claim 1, wherein the light-emitting regions and the TFT regions of the plurality of OLED units in the at least one camera region are arranged and combined with an overlapping portion and at least one non-overlapping portion.

5. The OLED display panel according to claim 4, wherein the overlapping portion is disposed in the at least one TFT collection region.

6. The OLED display panel according to claim 1, wherein the at least one TFT collection region in the at least one camera region is strip-shaped, and a portion of the light-emitting regions corresponding to the TFT regions in at least one the TFT collection region are disposed on a side or both sides of the at least one strip-shaped TFT collection region.

7. The OLED display panel according to claim 1, wherein the at least one TFT collection region in the at least one camera region is in a grid shape.

8. The OLED display panel according to claim 1, wherein each of the OLED units corresponds to a sub-pixel.

9. The OLED display panel according to claim 2, further comprising a non-camera region, wherein the non-camera region comprises at least one trace electrically connected to the light-emitting regions and the TFT regions of the OLED units in the non-camera region, wherein a size of the transparent metal trace in the at least one camera region is less than a size of the at least one trace in the non-camera region.

10. An organic light-emitting diode (OLED) display panel, comprising:
a plurality of OLED units, each of the OLED units comprising a light-emitting region and a thin film transistor (TFT) region electrically connected to the light-emitting region, wherein the OLED display panel further comprises:
at least one camera region configured to receive a camera, and
at least one TFT collection region disposed in the at least one camera region, wherein the TFT regions of the OLED units disposed in the at least one camera region are disposed in the at least one TFT collection region,
wherein the light-emitting region of each of the OLED units in the at least one camera region is connected to the corresponding TFT region in the at least one TFT collection region through a transparent metal trace, and the light-emitting regions of a portion of the OLED units in the at least one camera region overlap with the at least one TFT collection region.

11. The OLED display panel according to claim 10, wherein the light-emitting regions and the TFT regions of the plurality of OLED units in the at least one camera region are arranged and combined with an overlapping portion and at least one non-overlapping portion.

12. The OLED display panel according to claim 11, wherein the overlapping portion is disposed in the at least one TFT collection region.

13. The OLED display panel according to claim 10, wherein the at least one TFT collection region in the at least one camera region is strip-shaped, and a portion of the light-emitting regions corresponding to the TFT regions in the at least one TFT collection region are disposed on a side or both sides of the at least one strip-shaped TFT collection region.

14. The OLED display panel according to claim 10, wherein the at least one TFT collection region in the at least one camera region is in a grid shape.

15. The OLED display panel according to claim 10, wherein each of the OLED units corresponds to a sub-pixel.

16. The OLED display panel according to claim 10, further comprising a non-camera region, wherein the non-camera region comprises at least one trace electrically connected to the light-emitting regions and the TFT regions of the OLED units in the non-camera region, wherein a size of the transparent metal trace in the at least one camera region is less than a size of the at least one trace in the non-camera region.

17. A display device comprising:
an organic light-emitting diode (OLED) display panel comprising a plurality of OLED units, each of the OLED units comprising a light-emitting region and a thin film transistor (TFT) region electrically connected to the light-emitting region, wherein the OLED display panel further comprises at least one camera region and at least one TFT collection region disposed in the at least one camera region, wherein the TFT regions of each of the OLED units disposed in the at least one camera region are disposed in the at least one TFT collection region; and
a camera disposed in the at least one camera region.

18. The display device according to claim 17, wherein the light-emitting region of each of the OLED units in the at least one camera region is connected to the corresponding TFT region in the at least one TFT collection region through a transparent metal trace.

19. The display device according to claim 17, wherein the light-emitting regions and the TFT regions of the plurality of OLED units in the at least one camera region are arranged and combined with an overlapping portion and at least one non-overlapping portion.

20. The display device according to claim 17, further comprising a non-camera region, wherein the non-camera region comprises at least one trace electrically connected to the light-emitting regions and the TFT regions of the OLED units in the non-camera region, wherein a size of the transparent metal trace in the at least one camera region is less than a size of the at least one trace in the non-camera region.
